(19) United States
(12) Patent Application Publication
(10) Pub. No.: US 2022/0029063 A1
(43) Pub. Date: Jan. 27, 2022

(54) OPTICAL FILM AND LIGHT EMITTING DEVICE INCLUDING THE SAME

(71) Applicant: Lextar Electronics Corporation, Hsinchu (TW)

(72) Inventors: Chih-Hao LIN, Hsinchu (TW); Kang-Hung LIU, Hsinchu (TW)

(21) Appl. No.: 16/940,340

(22) Filed: Jul. 27, 2020

(51) Int. Cl. H01L 33/46; H01L 27/15; H01L 33/60

(52) U.S. Cl. CPC H01L 33/465; H01L 33/60; H01L 27/156

(57) ABSTRACT

An optical film includes a first transparent layer and a reflective coating. The first transparent layer has a light input surface and a light output surface. A plurality of cavities are formed on the light input surface, wherein each cavity has a first linear sidewall and a second linear sidewall, the second linear sidewall is inclined to the first linear sidewall. The reflective coating is formed on the second linear sidewall of each cavity.

### BACKGROUND

### Field of Invention

The present disclosure relates to an optical film and a light emitting device including the optical film.

### Description of Related Art

Light emitting diode (LED) is a light-emitting element made of semiconductor material that can convert electrical energy into light. It has the advantages of small size, high energy conversion efficiency, long life, power saving, etc., so it can be widely used as light source in various electronic applications.

As the LED is needed in the biometrics sensor application, it is urgent to provide a thin-profiled biometrics sensor to be installed on a wearable electronic device.

### SUMMARY

One aspect of the present disclosure is to provide an optical film including a first transparent layer and a reflective coating. The first transparent layer has a light input surface and a light output surface. A plurality of cavities are formed on the light input surface, wherein each cavity has a first linear sidewall and a second linear sidewall, the second linear sidewall is inclined to the first linear sidewall. The reflective coating is formed on the second linear sidewall of each cavity.

Another aspect of the present disclosure is to provide a light emitting device including a substrate, a plurality of LEDs on the substrate, a first transparent layer and a reflective coating. The first transparent layer is formed over the LEDs, the first transparent layer has a light input surface and a light output surface, the light input surface faces the LEDs. A plurality of cavities are formed on the light input surface, wherein each cavity has a first linear sidewall and a second linear sidewall, the second linear sidewall is inclined to the first linear sidewall. The reflective coating is formed on the second linear sidewall of each cavity.

In one or more embodiments, the first linear sidewall is parallel to a perpendicular line of the light input surface.

In one or more embodiments, the second linear sidewall is inclined to the light input surface.

In one or more embodiments, the first transparent layer is made from a thermal curable material.

In one or more embodiments, the first transparent layer is made from an ultraviolet light curable material.

In one or more embodiments, the optical film further includes a second transparent layer formed on the light output surface of the first transparent layer.

In one or more embodiments, the optical film further includes a plurality of micro optical lens formed on the second transparent layer, each lens is aligned with a corresponding one of the cavities formed on the light input surface.

In one or more embodiments, the optical film further includes a plurality of micro optical lens formed on the light output surface, each lens is aligned with a corresponding one of the cavities formed on the light input surface.

In one or more embodiments, the reflective coating is not formed on the first linear sidewall.

In one or more embodiments, the cavities occupy at least 80 percent of an area of the light output surface.

In summary, the light emitting device disclosed herein includes an optical film to deflect its output light towards a desired direction. The optical film has a thickness ranging from about 50 microns to about 100 microns such that the light emitting device can be installed on a wearable electronic device with a thin and compact profile.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 illustrates a cross-sectional view of an optical film in accordance with an embodiment of the present disclosure;

FIG. 2 illustrates a cross-sectional view of a light emitting device in accordance with an embodiment of the present disclosure;

FIG. 3 illustrates a cross-sectional view of an optical film in accordance with another embodiment of the present disclosure;

FIG. 4 illustrates a cross-sectional view of an optical film in accordance with still another embodiment of the present disclosure;

FIG. 5 illustrates a cross-sectional view of an optical film in accordance with still another embodiment of the present disclosure; and

FIG. 6 illustrates a cross-sectional view of an optical film in accordance with still another embodiment of the present disclosure.

### DETAILED DESCRIPTION

It is to be noted that the following descriptions of preferred embodiments of this disclosure are presented herein for purpose of illustration and description only. It is not intended to be exhaustive or to be limited to the precise form disclosed. Also, it is also important to point out that there may be other features, elements, steps and parameters for implementing the embodiments of the present disclosure which are not specifically illustrated. Thus, the specification and the drawings are to be regard as an illustrative sense rather than a restrictive sense. Various modifications and similar arrangements may be provided by the persons skilled in the art within the spirit and scope of the present disclosure. In addition, the illustrations may not be necessarily be drawn to scale, and the identical elements of the embodiments are designated with the same reference numerals.

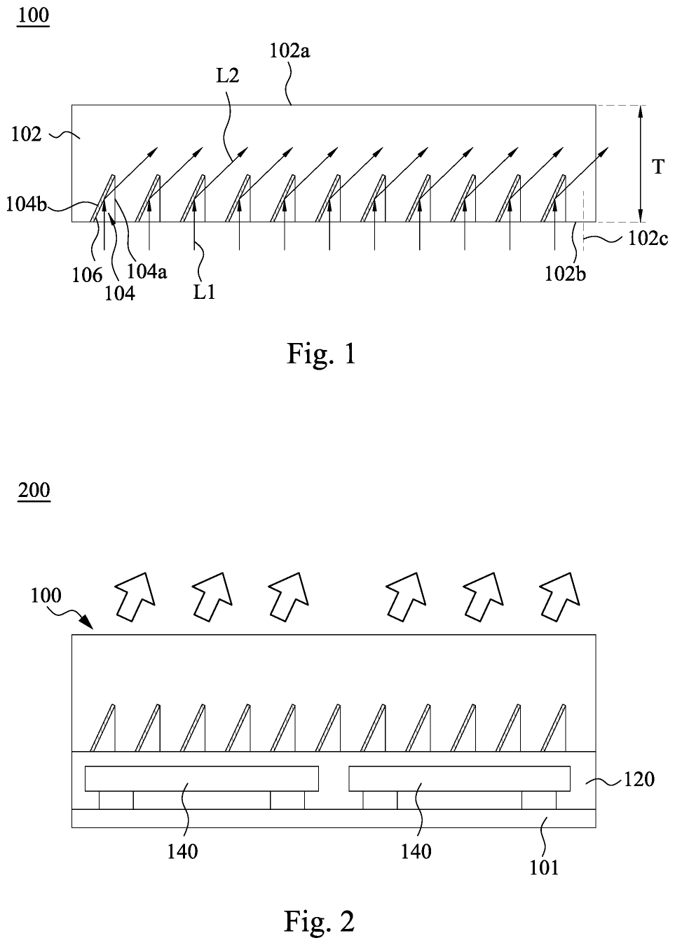

Referring to FIG. 1, which illustrates a cross-sectional view of an optical film in accordance with an embodiment of the present disclosure. An optical film 100 includes a first transparent layer 102 with a light input surface 102b and a light output surface 102a. A plurality of cavities 104 are formed on the light input surface 102b. Each cavity 104 has a first linear sidewall 104a and a second linear sidewall 104b, and the second linear sidewall 104b is inclined to the first linear sidewall 104a, i.e., not perpendicular to the first linear sidewall 104a, such that each cavity 104 has a triangular cross-section. A reflective coating 106 is formed on the second linear sidewall 104b of each cavity 104 for directing an incident light L1 towards a desired direction as an output light L2. The output light L2 may be directed to an object to be detected and then sensed by a photo diode (not shown in the drawings).

In this embodiment, all the cavities 104 are voids, e.g., containing air, except for the reflective coating 106 formed on the second linear sidewall 104b, but not being limited thereto.

In this embodiment, the first linear sidewall 104a is parallel to a perpendicular line 102c of the light input surface 102b, but not being limited thereto.

In this embodiment, the second linear sidewall 104b is inclined to the light input surface 102b, i.e., not perpendicular to the light input surface 102b, but not being limited thereto.

In this embodiment, the second linear sidewall 104b is inclined to the perpendicular line 102c of the light input surface 102b, but not being limited thereto.

In this embodiment, the cavities 104 may be formed by mechanically pressing the light input surface 102b of the first transparent layer 102, but not being limited thereto.

In this embodiment, the reflective coating 106 may be coated on the second linear sidewall 104b of each cavity 104 by a proper film deposition, photo lithography and etching process, but not being limited thereto.

In this embodiment, the reflective coating 106 is not formed on the first linear sidewall 104a of each cavity 104.

In this embodiment, all the cavities 104 may occupy at least 80 percent of an area of the light input surface 102b to achieve the desired function, but not being limited thereto.

In this embodiment, the first transparent layer 102 may have a thickness T ranging from about 50 microns to about 100 microns, but not being limited thereto. The first transparent layer 102 may be made from polyethylene terephthalate, polycarbonate, polyimide or polyethylene naphthalate, but not being limited thereto.

Referring to FIG. 2, which illustrates a cross-sectional view of a light emitting device 200 in accordance with an embodiment of the present disclosure. The light emitting device 200 includes the optical film 100 located over LEDs 140. The LEDs 140 are mounted on a substrate 101, e.g., a printed circuit board. An optical clear adhesive 120 is used to attach the optical film 100 over the LEDs 140. The light input surface of the optical film 100 faces towards the LEDs 140 such that the optical film 100 can direct lights emitted from the LEDs 140 towards the desired directions.

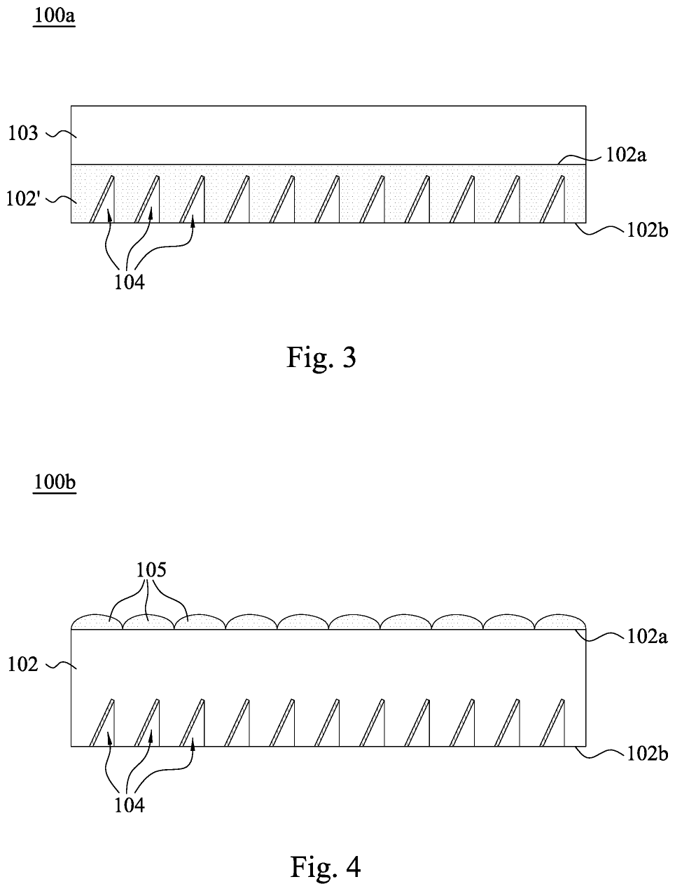

Referring to FIG. 3, which illustrates a cross-sectional view of an optical film 100a in accordance with another embodiment of the present disclosure. The optical film 100a differs from the optical film 100 mainly in that a second transparent layer 103 is located on the light output surface 102a of the first transparent layer 102′. In this embodiment, the first transparent layer 102′ may be made form a thermal curable material or ultraviolet light curable material such that first transparent layer 102′ can be molded to form the cavities 104 on the light input surface 102b, but not being limited thereto. In this embodiment, the first and second transparent layers may have a total thickness sum ranging from about 50 microns to about 100 microns, but not being limited thereto. The optical film 100a can also be bonded over the over LEDs 140 similar to the optical film 100 in FIG. 2.

Referring to FIG. 4, which illustrates a cross-sectional view of an optical film 100b in accordance with still another embodiment of the present disclosure. The optical film 100b differs from the optical film 100 mainly in that a plurality of micro optical lenses 105 are formed on the light output surface 102a of the first transparent layer 102. Each lens 105 is aligned with a corresponding cavity 104 formed on the light input surface 102b of the first transparent layer 102. The optical film 100b can also be bonded over the over LEDs 140 similar to the optical film 100 in FIG. 2.

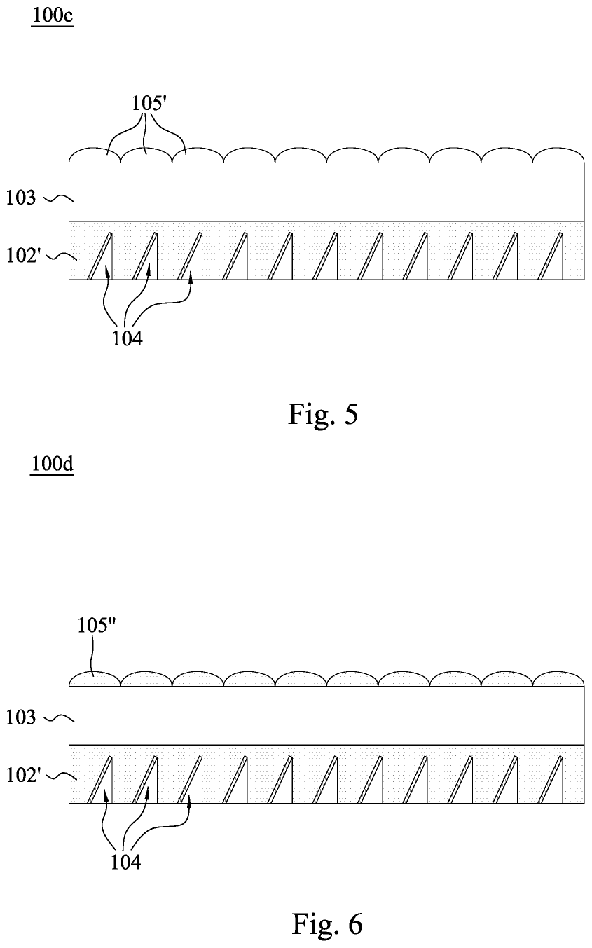

Referring to FIG. 5, which illustrates a cross-sectional view of an optical film 100c in accordance with still another embodiment of the present disclosure. The optical film 100c differs from the optical film 100a mainly in that a plurality of micro optical lenses 105′ are formed on the second transparent layer 103. Each lens 105′ is aligned with a corresponding cavity 104 formed on the light input surface 102b of the first transparent layer 102′. In this embodiment, the micro optical lenses 105′ and the second transparent layer 103 are of the same material, but not being limited thereto. The optical film 100c can also be bonded over the over LEDs 140 similar to the optical film 100 in FIG. 2.

Referring to FIG. 6, which illustrates a cross-sectional view of an optical film 100d in accordance with still another embodiment of the present disclosure. The optical film 100d differs from the optical film 100c mainly in that the micro optical lenses 105″ and the second transparent layer 103 are made from different materials. The optical film 100d can also be bonded over the over LEDs 140 similar to the optical film 100 in FIG. 2.

In summary, the light emitting device disclosed herein includes an optical film to deflect its output light towards a desired direction. The optical film has a thickness ranging from about 50 microns to about 100 microns such that the light emitting device can be installed on a wearable electronic device with a thin and compact profile.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. An optical film comprising:
a first transparent layer having a light input surface and a light output surface;
a plurality of cavities formed on the light input surface, wherein each cavity has a first linear sidewall and a second linear sidewall, the second linear sidewall is inclined to the first linear sidewall; and
a reflective coating formed on the second linear sidewall of each cavity.

2. The optical film of claim 1, wherein the first linear sidewall is parallel to a perpendicular line of the light input surface.

3. The optical film of claim 1, wherein the second linear sidewall is inclined to the light input surface.

4. The optical film of claim 1, wherein the first transparent layer comprises a thermal curable material.

5. The optical film of claim 1, wherein the first transparent layer (102′) comprises an ultraviolet light curable material.

6. The optical film of claim 1 further comprising a second transparent layer (103) disposed on the light output surface of the first transparent layer.

7. The optical film of claim 6 further comprising a plurality of micro optical lens disposed on the second transparent layer, each lens is aligned with a corresponding one of the cavities formed on the light input surface.

8. The optical film of claim 1 further comprising a plurality of micro optical lens disposed on the light output surface, each lens is aligned with a corresponding one of the cavities formed on the light input surface.

9. The optical film of claim 1, wherein the reflective coating is not formed on the first linear sidewall.

10. The optical film of claim 1, wherein the cavities occupy at least 80 percent of an area of the light input surface.

11. A light emitting device comprising:
a substrate;
a plurality of LEDs disposed on the substrate;
a first transparent layer disposed over the LEDs, the first transparent layer having a light input surface and a light output surface, the light input surface facing the LEDs;
a plurality of cavities formed on the light input surface, wherein each cavity has a first linear sidewall and a second linear sidewall, the second linear sidewall is inclined to the first linear sidewall; and
a reflective coating formed on the second linear sidewall of each cavity.

12. The light emitting device of claim 11, wherein the first linear sidewall is parallel to a perpendicular line of the light input surface.

13. The light emitting device of claim 11, wherein the second linear sidewall is inclined to the light input surface.

14. The light emitting device film of claim 11, wherein the first transparent layer comprises a thermal curable material.

15. The light emitting device of claim 11, wherein the first transparent layer comprises an ultraviolet light curable material.

16. The light emitting device of claim 11 further comprising a second transparent layer disposed on the light output surface of the first transparent layer.

17. The light emitting device of claim 16 further comprising a plurality of micro optical lens disposed on the second transparent layer, each lens is aligned with a corresponding one of the cavities formed on the light input surface.

18. The light emitting device of claim 11 further comprising a plurality of micro optical lens disposed on the light output surface, each lens is aligned with a corresponding one of the cavities formed on the light input surface.

19. The light emitting device of claim 11, wherein the reflective coating is not formed on the first linear sidewall.

20. The light emitting device of claim 11, wherein the cavities occupy at least 80 percent of an area of the light input surface.
